(19) United States
(12) Patent Application Publication
(10) Pub. No.: US 2009/0214858 A1
(43) Pub. Date: Aug. 27, 2009

(54) Magnesium oxide coated glass article and a method for depositing magnesium oxide coatings on flat glass

(75) Inventors: Srikanth Varanasi, Toledo, OH (US); David A. Strickler, Toledo, OH (US)

Correspondence Address: MARSHALL & MELHORN, LLC, FOUR SEAGATE - EIGHTH FLOOR, TOLEDO, OH, 43604, US

(73) Assignee: Pilkington North America, Inc.

(21) Appl. No.: 12/072,243

(22) Filed: Feb. 25, 2008

(51) Int. Cl. B32B 17/06; C23C 16/40

(52) U.S. Cl. 428/336; 428/432; 427/255.19

(57) ABSTRACT

An atmospheric chemical vapor deposition process for laying down a magnesium oxide coating on a moving glass substrate through the reaction of an organic ester and an organomagnesium compound. The resulting article has a magnesium oxide coating which can be of substantial thickness because of the high deposition rates attainable with the novel process. Preferably, the coating deposition rates resulting from the method of the present invention may be greater than or equal to 15 Å per second.

### BACKGROUND

This invention relates to a process for depositing magnesium oxide coatings on a flat glass substrate. More particularly, this invention relates to an atmospheric pressure chemical vapor deposition process for producing magnesium oxide coatings at high growth rates on flat glass.

Due to a number of desirable physical and chemical properties, magnesium oxide coatings have been used, primarily, in connection with semiconductor display panels.

It has been known to use esters as a source of oxygen in combination with organic and inorganic transition metal compounds to form metal oxide thin films. It has not been known, however, to use esters in combination with alkaline earth metals to form metal oxide thin films by atmospheric chemical vapor deposition processes, for example, during the float glass manufacturing process.

Growth of magnesium oxide coatings by CVD has been reported in the scientific literature. (Kamata et al., J. Mat. Sci. Lett. 1984, 3, 423; Kwak et al., Appl. Phys. Lett., 1989, 54, 2452 and Maruyama and Shionoya, Jpn. J. Appl. Phys., 1990, 29, L810.)

Further, deposition of magnesium oxide coatings utilizing dicyclopentadienyl magnesium (Cp₂Mg) has been reported under atomic layer conditions using water as a hydrolysis source (Huang and Kitai; Appl. Phys. Lett., 1992, 61 (12), 1450).

Additionally, di(dipivaloylmethanato)magnesium, Mg(dpm)₂, has been used to grow homoepitaxial magnesium oxide coatings on magnesium oxide substrates for superconductor film growth (W. Fan et al., Mat Chem. & Phys., 70(2), 191-196, May 2001).

Deposition of magnesium oxide films has also been reported in the patent literature.

U.S. Pat. No. 5,776,621 describes the deposition of a thin film stack formed on a semiconductor single crystal substrate, wherein the film stack includes a buffer thin film, which buffer thin film may be made of MgO or MgAl₂O₄. CVD is mentioned as a method of deposition which may be utilized for the deposition of one or more of the layers of the film stack.

U.S. Pat. No. 5,955,146 describes a process for coating the surface of a single crystal with a magnesium oxide film which comprises contacting an organomagnesium compound having an oxygen to magnesium atomic ratio of 1:1 with the crystal heated to a temperature ranging from 300° C. to 450° C. in the absence of oxygen. The magnesium oxide film thus produced is said to have a negligible amount of residual carbon.

U.S. Pat. No. 6,017,579 describes a method for making magnesium oxide layers in plasma displays. A magnesium carboxylate liquid precursor solution is applied to a display panel, dried and annealed to yield a magnesium oxide layer said to have excellent electro-optical performance. CVD is mentioned as a possible method of deposition.

U.S. Pat. No. 6,800,133 describes a CVD method for growing MgO on a Si substrate coated with a cubic SiC buffer layer which method is said to provide a single-crystalline MgO film.

It would be desirable to form magnesium oxide films at essentially atmospheric pressure and to produce them at deposition rates compatible with time-critical manufacturing processes, for example, production of flat glass by the well-known float method. Those skilled in the art have continued to search for a method of producing magnesium oxide films meeting the above-noted criteria in order to have available, affordable films for optical thin film stack designs.

### SUMMARY OF THE INVENTION

In accordance with the present invention, there is provided an atmospheric chemical vapor deposition (APCVD) process for laying down a magnesium oxide coating on a moving hot glass substrate using a precursor gas mixture containing an organomagnesium compound, an organic ester, and optionally including molecular oxygen at a deposition rate of greater than or equal to 15 Å per second.

Preferably, the present invention provides a process for depositing a magnesium oxide coating on a hot glass substrate comprising the steps of: preparing a precursor gas mixture containing dicyclopentadienyl magnesium (Cp₂Mg) and ethyl acetate; maintaining the precursor gas mixture at a temperature below the temperature at which the Cp₂Mg reacts with the ethyl acetate to form the magnesium oxide while delivering the mixture to a coating chamber opening onto the hot glass, and introducing the precursor gas mixture into the coating chamber whereby the mixture is heated to a temperature sufficient to cause reaction of the organomagnesium compound and the ethyl acetate to cause deposition of the magnesium oxide, by incorporating oxygen from the ethyl acetate, onto the hot glass surface. The coating thus formed has an intermediate refractive index on the order of 1.6 to 1.7.

### DESCRIPTION OF THE INVENTION

The invention relates to a process for depositing a magnesium oxide coating on a moving hot glass substrate, at substantially atmospheric conditions.

Organic esters containing 3 to 18 carbon atoms may be used with the invention, however, it is preferred to use organic esters containing from 3 to 6 carbon atoms, since larger molecules tend to be less volatile and hence less convenient for use in the CVD process of the present invention.

Esters useful as precursor materials in connection with the present invention can be described by the following formula:

R₁—C(═O)—O—CR₂R₃R₄

where R₁-R₃ is H, or a short chain, saturated organic group having 1 to 4 carbon atoms and R₄ is a short chain, saturated organic group having 1 to 4 carbon atoms. In the structure illustrated in the formula noted above, a β hydrogen which is useful in connection with the present invention may occupy the β position in the structure of R₂, R₃ and R₄.

Preferred esters for use as sources of oxygen in the practice of the present invention include ethyl acetate, isobutyl acetate, n-butyl acetate and ethyl formate. Additional oxygen sources may include carboxylic acids such as acetic acid. A particularly preferred organic source of oxygen is ethyl acetate.

The method of the present invention is generally practiced in connection with the formation of a continuous glass ribbon substrate, for example during a float glass production process.

The present invention involves the preparation of a precursor gas mixture, including an organomagnesium compound, preferably Cp₂Mg, or a derivative such as a halogenated Cp₂Mg and an organic ester. Molecular oxygen may optionally be included in the gas mixture. A carrier gas or diluent, for example, nitrogen, or helium, will normally also be included in the gas mixture. Since thermal decomposition of the organic solvent may initiate the magnesium oxide deposition reaction at a high rate, it is desirable that the precursor mixture be kept at a temperature below the thermal decomposition temperature of the organic ester to prevent prereaction of the gaseous mixture resulting in formation of the magnesium oxide.

The gaseous mixture is maintained at a temperature below that at which it reacts to form the magnesium oxide, and is delivered to a location near a flat glass substrate to be coated, the substrate being at a temperature above the reaction temperature (and above the decomposition temperature of the ester in the precursor gas mixture).

The precursor gas mixture is thereafter introduced into the vapor space directly over the substrate. The heat from the substrate in the coating chamber raises the temperature of the precursor gas mixture above the thermal decomposition temperature of the organic oxygen compound. The organic ester then decomposes and, by reaction with the Cp₂Mg, produces a magnesium oxide coating on the substrate.

While the exact role of the organic bond in the deposition of magnesium oxides from Cp₂Mg has not been established, one plausible mechanism is as follows:
1. The ester undergoes an intra-molecular gas phase pyrolytic elimination to give the corresponding carboxylic acid and an olefin.
2. The carboxylic acid produced in step 1 dehydrates intra-molecularly, via further pyrolysis, to provide water and a ketene.
3. The water generated in step 2 then reacts with Cp₂Mg to give magnesium oxide via hydrolysis.
   If the organic ester first reacts with Cp₂Mg to give a Lewis acid-base complex, it does not necessarily preclude the proposed mechanism (steps 1-3) from taking place.

The present invention permits the production of magnesium oxide coatings deposited on a moving hot glass substrate at a high deposition rate. Preferably, the magnesium oxide coatings are deposited at a thickness of over 200 Å. High deposition rates are important when coating substrates in a manufacturing process. This is particularly true for an on-line float glass process where the glass ribbon is traveling at a specific line speed on the order of several hundred inches per minute, and where a specific coating thickness is required. The deposition rates obtained with the preferred embodiments of the present invention under static deposition conditions were equal to 15 Å/sec. It is anticipated that higher deposition rates will be obtained in a production environment under optimized dynamic deposition conditions. The greatest deposition rate for the present invention was achieved using a precursor gas mixture including Cp₂Mg and EtOAC. Molecular oxygen may also be included in the precursor mixture.

The deposition rate is dependent upon the particular ester used, and the concentrations of both the ester and the organomagnesium compound, as well as the temperature of the glass. For any particular combination of compounds, the optimum concentrations (and in particular the optimum proportion of the ester to the organomagnesium compound) and flow rates for rapid coating deposition may be determined by simple trial. The flow rate of the reactant mixture can vary slightly until the chemical delivery process reaches equilibrium. It will be appreciated that the use of higher concentrations of reactants and high gas flow rates is likely to result in a less efficient overall conversion of the reactants into a coating, so that the optimum condition for commercial operation may differ from the conditions which provide the highest deposition rates.

However, when the process is held stable and the flowrate of the reactant gas mixture is delivered to the surface of the glass substrate at a constant rate the gas mixture composition may be the only variable that can affect deposition rate. Therefore, varying the amount of a reactant gases may be necessary to achieve a desired deposition rate or film thickness. Thus, the invention may preferably include from about 0 to 15% oxygen, from about 1% to about 4% organomagnesium compound, and from about 1% to 8% organic ester.

Magnesium oxide coatings have two important properties not shared by other currently deposited on-line thin films in the flat glass industry.

First, magnesium oxide coatings can operate as a barrier layer between the glass substrate and an electroceramic coating. Electroceramic coatings are highly desirable because they can act as superconductors and ferroelectrics. However, depositing high quality electroceramic films is only possible under certain conditions. One important deposition requirement for electroceramics is a homoepitaxial substrate. A glass substrate is an isotropic material. Thus, its lattice structure has no direction. Superconducting films require a homoepitaxial substrate for growth. This means that the lattice structure and orientation or lattice symmetry of the superconducting material must match that of the substrate on which it is deposited. Magnesium oxide, zirconium oxide, and electroceramics share the same lattice structure and orientation. Therefore, deposition of a layer of magnesium oxide as a buffer layer on a glass substrate would allow for deposition of an electroceramic film on a glass substrate, homoepitaxially.

Second, the magnesium oxide coatings produced by the inventive method on-line have been found to have refractive index values in the range of 1.6-1.7, in the visible region of the electromagnetic spectrum. Transparent thin films with refractive indices in this range permit the achievement of desired optical effects, especially when used in combination with other coating layers.

In some on-line low-emissivity coating products a two component interlayer is used to act as a barrier between the low-emissivity layer and the glass substrate. The interlayer helps to maintain color uniformity across the glass ribbon when the low-emissivity coating layer is not uniform by suppressing iridescence.

The first component of the interlayer is a coating deposited onto and adhering to the glass substrate typically with a higher refractive index than the second component in the visible spectrum. This first component also provides a barrier which prevents minerals from the glass substrate below from moving into the low-emissivity coating above. A second component, having a low refractive index, is deposited on and adheres to the first component of the interlayer. The second component also serves as a nucleation surface for additional thin film coatings deposited later in the float glass process. The combination of the first and second component suppresses iridescence. A magnesium oxide coating can act as the first component of the interlayer by providing a barrier layer on the glass surface and in combination with a lower refractive indexed second coating component can suppress iridescence.

Furthermore, magnesium oxide deposited in accordance with the method of the invention can be employed in an anti-reflective coating arrangement on either a monolithic glass substrate or on a laminated glass article. Anti-reflective coatings on glass are utilized to reduce the surface reflection of optical components and to reduce the reflectance of an interface between optical media with different refractive indices. The reduction of visible reflection is achieved by the principle of optical interference. Visible light reflection occurs when light impinges on the air-film, film-film, and film-glass interfaces because a portion of the beam is reflected at each interface.

A film stack deposited on a monolithic glass substrate comprising thin films with refractive indices configured in a medium/high/low arrangement allows individual reflected light beams to be destructively interfered. Thus, the observed visible surface reflectance is reduced. An example of the medium/high/low arrangement on a glass substrate comprises: a glass substrate, a thin film of magnesium oxide adhered to the glass substrate, a high refractive index thin film such as fluorine doped tin oxide adhered to the magnesium oxide layer, and a thin film having a refractive index less than the magnesium oxide film adhered to the fluorine doped tin oxide layer.

In this arrangement, there are several thin films with a low refractive index that can be used as the third coating. They include metal oxides such as silicon dioxide and other low refractive index films such as magnesium fluoride. Additionally, there are other high refractive index films capable of being used as the second coating. These include metal oxide films of titanium and zirconium, highly conductive metal oxide films such as indium oxide, and mixed metal oxides films such as chromium titanium oxide and cadmium stannate.

Medium/high/low monoliths can also be laminated together to further reduce surface reflection. The laminated article is preferably constructed so that the coated surfaces face outward. The laminated article would then be arranged as low/high/medium/glass substrate/interlayer/glass substrate/medium/high/low. A glass article is typically laminated with an interlayer of polyvinyl butyral, PVB.

A float glass installation may be utilized as a means for practicing the method of the present invention. The float glass apparatus, more particularly, comprises a canal section along which molten glass is delivered from a melting furnace, to a float bath section wherein a continuous glass ribbon is formed in accordance with the well-known float process. The glass ribbon advances from the bath section through an adjacent annealing lehr and a cooling section. The continuous glass ribbon serves as the substrate upon which the magnesium oxide coating is deposited in accordance with the present invention.

The float section includes a bottom section within which a bath of molten tin is contained, a roof, opposite sidewalls, and end walls. The roof, side walls, and end walls together define an enclosure in which a non-oxidizing atmosphere is maintained to prevent oxidation of the molten tin.

Additionally, gas distributor beams are located in the bath section. The gas distributor beams in the bath section may be employed to apply additional coatings onto the substrate prior to applying the magnesium oxide coating by the method of the present invention. The additional coatings may include silicon and silica.

In operation, the molten glass flows along the canal beneath a regulating tweel and downwardly onto the surface of the tin bath in controlled amounts. On the tin bath the molten glass spreads laterally under the influences of gravity and surface tension, as well as certain mechanical influences, and it is advanced across the bath to form the ribbon. The ribbon is removed over lift out rolls and is thereafter conveyed through the annealing lehr and the cooling section on aligned rolls. The application of the coating of the present invention may take place in the float bath section, or further along the production line, for example in the gap between the float bath and the annealing lehr, or in the annealing lehr.

A suitable non-oxidizing atmosphere, generally nitrogen or a mixture of nitrogen and hydrogen in which nitrogen predominates, is maintained in the bath enclosure to prevent oxidation of the tin bath. The atmosphere gas is admitted through conduits coupled to a distribution manifold. The non-oxidizing gas is introduced at a rate sufficient to compensate for normal losses and maintain a slight positive pressure, on the order of about 0.001 to about 0.01 atmosphere above ambient atmospheric pressure, so as to prevent infiltration of outside atmosphere. For purposes of the present invention the above-noted pressure range is considered to constitute normal atmospheric pressure. Heat for maintaining the desired temperature regime in the tin bath and the enclosure is provided by radiant heaters within the enclosure. The atmosphere within the lehr is typically atmospheric air, as the cooling section is not enclosed and the glass ribbon is open to the ambient atmosphere. Ambient air may be directed against the glass ribbon as by fans in the cooling section. Heaters may also be provided within the annealing lehr for causing the temperature of the glass ribbon to be gradually reduced in accordance with a predetermined regime as it is conveyed therethrough.

Gas distributor beams are generally, positioned in the float bath to deposit the various coatings on the glass ribbon substrate. The gas distributor beam described in U.S. Pat. No. 4,992,853, the disclosure of which patent is herein incorporated by reference, is one form of reactor that can be employed in practicing the process of the present invention.

A conventional configuration for the distributor beams suitable for supplying the precursor materials in accordance with the invention is generally an inverted, generally channel-shaped, framework formed by spaced inner and outer walls and defines enclosed cavities. A suitable heat exchange medium is circulated through the enclosed cavities in order to maintain the distributor beams at a desired temperature.

The precursor gas mixture is supplied through a fluid-cooled supply conduit. The supply conduit extends along the distributor beam and admits the gas through drop lines spaced along the supply conduit. The supply conduit leads to a delivery chamber within a header carried by the framework. Precursor gases admitted through the drop lines are discharged from the delivery chamber through a passageway toward a coating chamber defining a vapor space opening onto the glass where they flow along the surface of the glass.

Baffle plates may be provided within the delivery chamber for equalizing the flow of precursor materials across the distributor beam to assure that the materials are discharged against the glass in a smooth, laminar, uniform flow entirely across the distributor beam. Spent precursor materials are collected and removed through exhaust chambers along the sides of the distributor beam.

Various forms of distributor beams used for chemical vapor deposition are suitable for the present method and are known in the prior art.

One such alternative distributor beam configuration generally introduces the precursor gas mixture-through a gas supply duct where it is cooled by cooling fluid circulated through ducts. Gas supply ducts open through an elongated aperture into a gas flow restrictor.

The gas flow restrictor comprises a plurality of metal strips longitudinally crimped in the form of a sine wave and vertically mounted in abutting relationship with one another extending along the length of the distributor. Adjacent crimped metal strips are arranged “out of phase” to define a plurality of vertical channels between them. These vertical channels are of small cross-sectional area relative to the cross-sectional area of the gas supply duct, so that the gas is released from the gas flow restrictor at substantially constant pressure along the length of the distributor.

The coating gas is released from the gas flow restrictor into the inlet side of a substantially U-shaped guide channel generally comprising an inlet leg, coating chamber which opens onto the hot glass substrate to be coated, and exhaust outlet, whereby used coating gas is withdrawn from the glass. The rounded corners of the blocks defining the coating channel promote a uniform laminar flow of coating parallel to the glass surface across the glass surface to be coated.

### EXAMPLES

The following examples (in which gas volumes are expressed under standard conditions, i.e., one atmosphere pressure and ambient temperature, unless otherwise stated) which constitute the best mode presently contemplated by the inventors for practicing the invention, are presented solely for the purpose of further illustrating and disclosing the present invention, and are not to be construed as a limitation on, the invention.

The following experimental conditions are applicable to Examples 1-3.

A laboratory furnace having a 10-inch wide, bidirectional coater, the coater being suitable for distributing vaporized reactants to the surface of a glass substrate in order to form a film or film stack by chemical vapor deposition.

The glass substrates are heated to approximately 1170° F., while the coater, at the reactor face, or portion nearest the glass surface, is at a temperature of approximately 500° F.

Preparation and containment of the Cp₂Mg and EtoAc precursor material is accomplished by utilizing multiple source chambers known as “bubblers”, there being one for each of these precursor materials which are maintained at specific temperatures. Helium gas is then introduced into the bubbler, at a particular flowrate.

Table 1 summarizes the deposition flow rates of the uniform, gaseous reactant mixture which is delivered to the surface of the hot glass substrate in accordance with the invention. The various reactants described below are combined in the coater to deposit a magnesium oxide on a static soda-lime-silica glass substrate whereon a SiO₂ layer 200 Å thick had been previously deposited.

TABLE 1
Glass Substrate/Silica/Magnesium Oxide

| Example | Carrier 1 | Carrier 2 | Cp2Mg | EtoAc | O₂ |
|---|---|---|---|---|---|
| 1 | 18He | 15He | 1 | .5 | 0 |
| 2 | 18He | 15He | 1 | 1.4 | 0 |
| 3 | 18He | 15He | 1 | 0 | 3 |

Note:
All flowrates are in SLPM.

Example 1 produced a film with a thickness less than Example 2. Example 2 produced a film with a thickness of 225 Å which was determined using ion beam sputtering and profilometry. The films obtained from Examples 1 and 2 had average refractive index values of 1.64 in the visible region of the electromagnetic spectrum. XPS analysis reveals that the stoichiometry of Example 2 is nearly 1:1 (Mg:O), and carbon incorporation in the film was low and limited to the surface of the coating. Example 3 did not produce a visible film.

In an embodiment of the present invention, a thin film of silicon dioxide is first deposited on the surface of the hot glass substrate, with the magnesium oxide layer deposited thereover. It can be preferable, when forming the magnesium oxide coating in accordance with this invention, to apply a layer of a material which acts as a sodium diffusion barrier between the glass substrate and the magnesium oxide coating. Coated glass articles have been found to exhibit lower haze when the magnesium oxide coating deposited in accordance with the invention is applied to the glass with a sodium diffusion layer there between, as opposed to directly on the glass. This sodium diffusion layer is preferably formed by silicon dioxide. The layer of silica may be formed using any suitable CVD technique, for example APCVD.

In another embodiment, a thin film of tin oxide is first deposited on the surface of the hot glass substrate, with a thin film of silica deposited thereover, so that an underlayer structure of tin oxide/silica is formed intermediate the glass and the subsequently deposited layer of magnesium oxide. In this embodiment, the silica film not only acts as a sodium diffusion barrier but, in combination with the first (undoped) tin oxide film, helps to suppress iridescence in the resulting coated glass article. The use of such anti-iridescent layers is disclosed in U.S. Pat. No. 4,377,613, which is incorporated herein in its entirety by reference thereto.

In another embodiment, a thin film of magnesium oxide is first deposited on the surface of the hot glass substrate, with a thin film of silica deposited thereover, so that an underlayer structure of magnesium oxide/silica is formed intermediate the glass and the subsequently deposited transparent thin film layers. In this embodiment, the silica film not only acts as a nucleation surface but also in combination with the first magnesium oxide film, helps to suppress iridescence in the resulting coated glass article.

It is also possible, when forming the magnesium oxide coating in accordance with this invention, to create an anti-reflective coating. The surface reflection of a piece of clear float glass substrate is approximately eight percent. A medium/high/low stack deposited on the float glass substrate using magnesium oxide as the medium indexed film can reduce the reflection to below five percent.

The anti-reflective coated glass article can be formed when a magnesium oxide coating is deposited in accordance with the invention to a glass substrate with a fluorine doped tin oxide layer thereover. Additionally, a thin film layer of silicon dioxide or magnesium fluoride adhering to the fluorine doped tin oxide layer would be deposited to achieve the medium/high/low refractive index arrangement.

Table 2 sets forth predictive examples of monolithic anti-reflective medium/high/low stack arrangements. The examples were generated using a thin film stack design manual, Thin Film Optical Filters, by H. A. Macleod.

TABLE 2
Anti-reflective Stack Arrangement(Medium/High/Low) on Glass

| | MgO | SnO₂:F | | | |
|---|---|---|---|---|---|
| Example | Thickness | Thickness | SiO₂ Thickness | Y | a*, b* |
| 4 | 100 | 1100 | 850 | 4.77 | −2.59, −6.34 |
| 5 | 150 | 1100 | 850 | 4.78 | −2.98, −5.68 |
| 6 | 200 | 1100 | 850 | 4.77 | −3.27, −4.98 |
| 7 | 250 | 1100 | 850 | 4.76 | −3.46, −4.26 |
| 8 | 300 | 1100 | 850 | 4.74 | −3.51, −3.57 |
| 9 | 350 | 1100 | 850 | 4.71 | −3.42, −2.94 |
| 10 | 400 | 1100 | 900 | 4.87 | −4.26, −2.16 |

Note:
All thicknesses are in Angstroms.

Medium/high/low monoliths can also be laminated together to further reduce surface reflection to below two percent. The laminated article would be arranged as SiO2/SnO2:F/MgO/Glass/PVB/Glass/MgO/SnO2:F /SiO2. Example 11 is then a laminated article comprising two glass substrates with a thickness of 125 mm, magnesium oxide film thicknesses of 400 Å on each glass substrate, fluorine doped tin oxide film thicknesses of 1100 Å, silicon dioxide film thicknesses of 900 Å, and a PVB interlayer. Example 11 has a visible light transmission of 90%, a visible light reflectance of 1.4%, and a* and b* values of −12.3 and −7.6, respectively.

It must be further noted that the process conditions are not sharply critical for the successful combining and delivering of vaporized reactants according to the present invention. The process conditions described hereinabove are generally disclosed in terms which are conventional to the practice of this invention. Occasionally, however, the process conditions as described may not be precisely applicable for each compound included within the disclosed scope. Those compounds for which this occurs will be readily recognizable by those ordinarily skilled in the art. In all such cases, either the process may be successfully performed by conventional modifications known to those ordinarily skilled in the art, e.g., by increasing or decreasing temperature conditions, by varying rates of combination of the reactants, by routine modifications of the vaporization process conditions, etc., or other process conditions which are otherwise conventional will be applicable to the practice of the invention.

It will also be noted that the process of the invention may be repeated as desired on a given substrate so as to form a coating consisting of several successive layers, the composition of each layer not necessarily being identical. It is, of course, obvious that for a given flow rate of the reactants, the thickness of a coating layer depends on the rate of movement of the substrate. The rate of substrate movement is typically described in inches per minute. Under these conditions, the reaction stations may, if desired, be multiplied by juxtaposing two or more coating devices. In this way, successive layers are superimposed before the layers have had time to cool, producing a particularly homogeneous overall coating.

The invention has been disclosed in which is considered to be its preferred embodiment. It must be understood, however, the specific embodiments are provided only for the purpose of illustration, and that the invention may be practiced otherwise than as specifically illustrated without departing from its spirit and scope.

What is claimed is:

1. An atmospheric chemical vapor deposition process for depositing a magnesium oxide coating on a surface of a hot, moving glass substrate comprising:
providing a uniform vaporized reactant mixture comprising an organomagnesium compound, an organic ester and an inert carrier gas;
maintaining the precursor gas mixture at a temperature below the temperature at which the organomagnesium compound reacts with the ester to form a magnesium oxide coating while delivering the gaseous mixture to a coating chamber which opens onto the hot glass substrate; and
introducing the precursor gas mixture into the coating chamber and directing the precursor gas mixture to a surface of the substrate, wherein the gaseous mixture is heated to above the reaction temperature of the organomagnesium and the ester and incorporates oxygen from the ester to cause the deposition of the magnesium oxide coating on the surface of the substrate at a deposition rate of greater than or equal to 15 Å per second.

2. The process for depositing the magnesium oxide coating on the substrate as recited in claim 1, wherein the ester is selected from the group consisting of ethyl formate, ethyl acetate, ethyl propionate, isopropyl formate, isopropyl acetate, n-butyl acetate, and t-butyl acetate.

3. The process for depositing the magnesium oxide coating on the glass substrate as recited in claim 1, wherein the organomagnesium compound comprises a dicyclopentadienyl magnesium.

4. The process for depositing the magnesium oxide coating on the substrate recited in claim 1, wherein the substrate is a float glass ribbon.

5. The process for depositing the magnesium oxide coating on the substrate recited in claim 5, where the precursor gas mixture flows over the float glass ribbon to be coated under laminar flow conditions.

6. The process for depositing the magnesium oxide coating on a substrate as recited in claim 4, wherein said float glass ribbon is at a temperature in the range of about 1100° F.-1320° F./590° C.-715° C.

7. The process for depositing the magnesium oxide coating on the substrate as recited in claim 1, wherein the organic ester is ethyl acetate and said substrate is a float glass ribbon.

8. The process for depositing the magnesium oxide coating on the substrate as recited in claim 1, wherein the substrate has a silica coating thereon, and said magnesium oxide coating is deposited over the silica coating.

9. The process for depositing the magnesium oxide coating on the glass substrate as recited in claim 1, wherein the organomagnesium compound in the precursor gas mixture is at a concentration of about 2-3.5% by volume.

10. The process for depositing the magnesium oxide coating on a glass substrate as recited in claim 2, wherein the ester in the precursor gas mixture is at a concentration of about 0.5 to 2 times the concentration of the organomagnesium compound.

11. The process for depositing the magnesium oxide coating on the glass substrate as recited in claim 1, wherein said magnesium oxide coating has an average refractive index of about 1.6-1.7 in the 400 to 800 nm range of the electromagnetic spectrum.

12. The process for depositing the magnesium oxide coating on the glass substrate as recited in claim 1, wherein said deposition process results in a deposition rate of 100 Å/sec. or more.

13. A glass article, comprising:
(a) a glass substrate having a surface,
(b) a two component iridescence-suppressing interlayer comprising a top transparent thin film of silicon dioxide and a bottom transparent thin film of magnesium oxide, deposited on and adhering to the surface of the glass substrate; and
(c) a first coating of a transparent thin film deposited on and adhering to said iridescence-suppressing interlayer.

14. A glass article, comprising:
(a) a glass substrate having a surface,
(b) a first coating comprising magnesium oxide, deposited on and adhering to the surface of the glass substrate,
(c) a second coating of a transparent thin film having a refractive index between 1.9 and 2.2 deposited on and adhering to said magnesium oxide first coating; and
(d) a third coating of a transparent thin film deposited on and adhering to said first coating to form a coated glass article, said second coating having a refractive index greater than a refractive index of said third coating.

15. A glass article as recited in claim 14, wherein the thickness of the magnesium oxide coating is between 100 and 400 Angstroms.

16. A glass article as recited in claim 14, wherein said second coating of a transparent thin film is selected from the group comprising metal oxides, mixed metal oxides, conductive metal oxides.

17. A glass article as recited in claim 15, wherein said metal oxides and conductive metal oxides include metals selected from the group consisting of tin, indium, zirconium, and titanium.

18. A glass article as recited in claim 14, wherein said third coating of a transparent thin film is selected from the group comprising metal oxides and magnesium fluoride.

19. A glass article as recited in claim 18, wherein said third coating of a transparent thin film is silicon dioxide.

20. A glass article as recited in claim 4, wherein the refractive index of the magnesium oxide coating is about 1.6-1.7 in the 400 to 800 nm range of the electromagnetic spectrum.
